(19) United States
(12) Patent Application Publication
(10) Pub. No.: US 2002/0113662 A1
(43) Pub. Date: Aug. 22, 2002

(54) Method of exchanging data with a temperature controlled crystal oscillator

(76) Inventors: Ammar Yasser Rathore, Emmaus, PA (US); Jaroslaw E. Adamski, Streamwood, IL (US); Richard N. Sutliff, South Elgin, IL (US); Iyad Alhayek, Schaumburg, IL (US)

Correspondence Address: Steven Weseman, CTS Corporation, 905 West Boulevard North, Elkhart, IN, 46514, US

(21) Appl. No.: 10/026,915

(22) Filed: Dec. 20, 2001

Related U.S. Application Data
(60) Provisional application No. 60/258,670, filed on Dec. 28, 2000.

(51) Int. Cl. H03L 1/00

(52) U.S. Cl. 331/176

(57) ABSTRACT

A method and apparatus are provided for exchanging data with a temperature controlled crystal oscillator chip. The method includes the steps of receiving data within the temperature controlled crystal oscillator chip through a first bonding pad of the chip during a first time interval and transmitting data from the temperature controlled crystal oscillator chip through the first bonding pad of the chip during a second time interval.

### FIELD OF THE INVENTION

The field of the invention relates to oscillators and more particularly to temperature controlled crystal oscillators.

### BACKGROUND OF THE INVENTION

Temperature controlled crystal oscillators (TCXOs) are generally known. Such devices are typically constructed in the form of a crystal and a controlling chip. Within the chip, a set of switchable capacitors and a feedback amplifier form a tank circuit that oscillates at a frequency determined by the number of capacitors switched into the tank circuit.

A temperature sensor is typically provided within the chip for sensing a temperature in the environs of the crystal. Based upon the temperature, a controller switches capacitors into and out of the tank circuit based upon a performance criteria of the tank circuit which is typically stored in a lookup table within the TCXO chip.

While prior art TCXOs work well, their structure and mode of operation is complex. The complexity of structure and operation requires equally complex software operations for particular applications. However, there is an ever present need to reduce the size and interface requirements of TCXOs. Accordingly a need exists for more streamlined means of communicating with TCXOs.

### SUMMARY

A method and apparatus are provided for exchanging data with a temperature controlled crystal oscillator chip. The method includes the steps of receiving data within the temperature controlled crystal oscillator chip through a first bonding pad of the chip during a first time interval and transmitting data from the temperature controlled crystal oscillator chip through the first bonding pad of the chip during a second time interval.

### BRIEF DESCRIPTION OF THE DRAWINGS

FIG. 1 is a block diagram of a TCXO system in accordance with an illustrated embodiment of the invention;

FIG. 2 is a block diagram of the TCXO system of FIG. 1 in conjunction with a programmer that may be used to program the TCXO;

FIG. 3 is a timing diagram that may be used with the system of FIG. 1;

FIG. 4 depict data frames that may be used with the system of FIG. 1; and

FIG. 5 depict data frames that may be used with the system of FIG. 1 under an alternate embodiment.

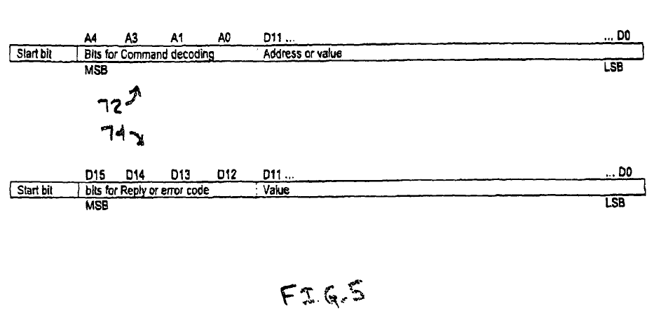

### DETAILED DESCRIPTION OF A PREFERRED EMBODIMENT

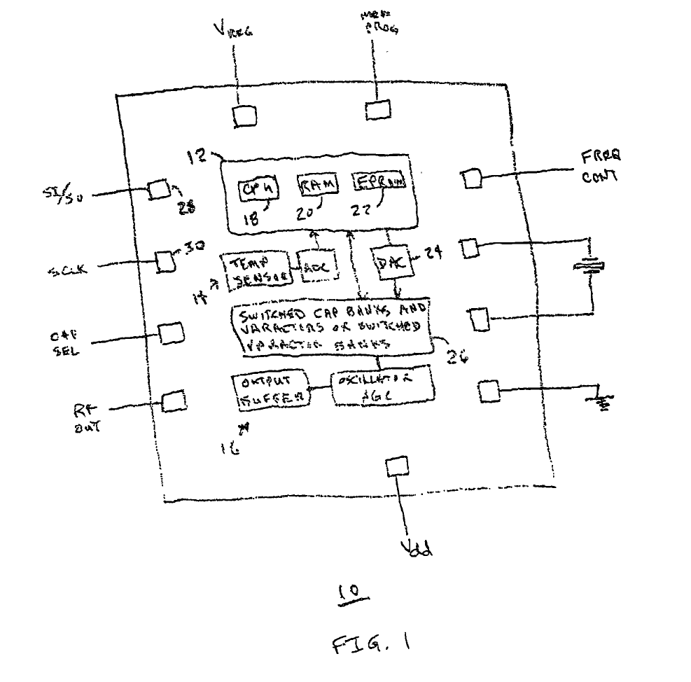

FIG. 1 is a TCXO chip 10 shown generally in accordance with an illustrated embodiment of the invention. Included within the TCXO 10 may be a digital controller 12, a temperature sensor 14 and oscillator circuit 26.

The digital controller 12 may contain a central processing unit (CPU) 18, a random access memory (RAM) 20 and electrically programmable read only memory (EPROM) 22. During operation, the CPU 18 may read a temperature from the temperature sensor 14 and retrieve a predetermined set of operating parameters for that temperature from the EPROM 22.

Upon retrieving the operating parameters, the CPU 18 may send a correction signal through the digital to analog converter 24 to the oscillator circuit 26 may send a set of instructions through the digital to analog converter (DAC) 24 to the oscillator circuit 26. The control signals may also be sent directly to the oscillator circuit 26 as well. The instructions may cause the oscillator circuit 26 to adjust its operating parameters to accommodate its current operating temperature. The imposition of a predetermined set of operating parameters for each temperature may allow the TCXO 10 to operate within a very small frequency deviation (e.g., less than one part per million (ppm)) over a relative broad temperature range.

In order to allow the TCXO 10 to conform to its published specifications, the TCXO 10 may be downloaded with one or more tables of temperature dependent operating parameters during manufacture. Once downloaded, the operating parameters may be stored in the EPROM 22 in the form of one or more lookup tables.

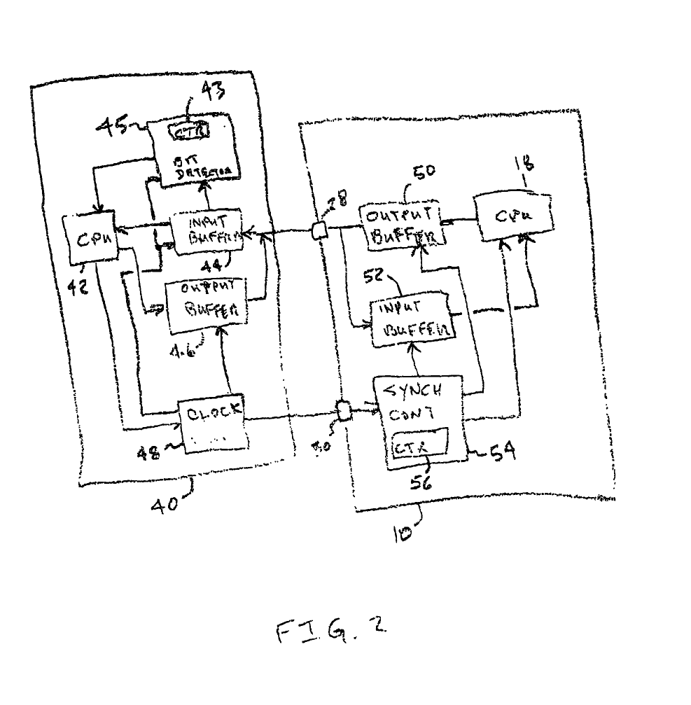

Under an illustrated embodiment of the invention, the downloading of instructions, operating parameters and, in general, communication with the CPU 18 may be accomplished using the arrangement shown in FIG. 2. As shown, the TCXO chip 10 may be coupled to an external programmer 40 through the serial input/serial ouput (SI/SO) bonding pad 28 and the serial clock (SCLK) bonding pad 30.

Under an illustrated embodiment, communications between the TCXO 10 and the programmer 40 may be initiated by a series of clock pulses transmitted from the programmer 40 to the TCXO 10 and received through the SCLK pad 30. Detection of the pulse train on the SCLK pad 30 may be used to cause the TCXO 10 to prepare to receive and/or transmit data.

Under the illustrated embodiment, the detection of the pulse train on the pad 30 may be used to initiate one or more communication frames. A complete communication frame may include an input data frame and an output data frame. Each communication frame may be divided into a first and second time interval. The first time interval may be dedicated to transferring the input frame from the programmer 40 to the TCXO 10. The second time interval may be used to transfer the output frame from the TCXO 10 to the controller 40.

Under the embodiment, the time intervals may be linked by reference to the pulse train. For example, the first time interval may be defined by a first predetermined number of clock pulses (e.g., the first seventeen pulses of the pulse train) applied to the pad 30. The second interval may be defined by a second predetermined number of clock pulses (e.g., the second set of seventeen pulses) applied to the terminal 30. The first time interval may not necessarily be the same interval length as the second time interval.

While the second time interval could immediately follow the first time interval, this will not always be the case. For example, where the first interval involves a command to be executed by the processor 18, the execution of that command may result in a delay between the first and second time intervals. Further, because the TCXO 10 has its own internal clock, it is not necessary that the clock be continually applied to the pad 30 between the first and second time intervals.

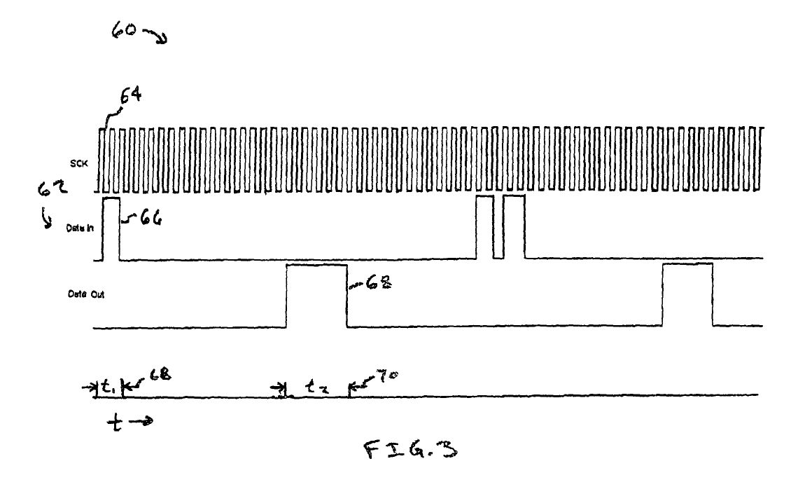

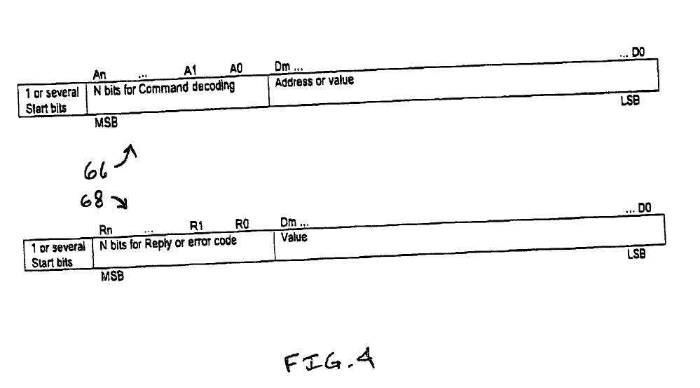

FIG. 3 depicts an exemplary timing diagram of a number of input/output (I/O) cycles that may transpire between the programmer 40 and TCXO 10 of FIG. 2. FIG. 4 depicts an input data frame 66 and an output data frame 68. Reference to FIGS. 3 and 4 shall be made as appropriate to an understanding of the invention.

As shown, a clock signal 60 may be applied to the SCLK pad 30 of the TCXO 10 from the programmer 40. At the falling edge of the first clock pulse 64, an input data frame 66 may begin. The input data frame 66 (FIG. 4) may include one or more start bits, n bits for command coding and m bits for an address or data value. In the example of FIG. 3 the first time period t₁ for transfer of the input data frame 66 is shown as having a length 68 substantially equal to two clock pulses.

During the input data frame 66, an output buffer 46 of the programmer 40 may be used to transfer data to the TCXO 10. A synch controller 54 within the TCXO 10 may detect the first clock pulse and trigger an input buffer 52 of the TCXO 10 on the falling edge of the first clock pulse to collect and store the input data. A pulse counter 56 within the synch controller 54 may be used to track the beginning and end of the first time interval. After the first time interval t₁, the programmer 40 may monitor the pad 28 for a response.

During the first time interval, the synch controller 54 may notify the CPU 18 of the initiation of a communication frame by the programmer 40. In response, the CPU 18 may retrieve input data frame 66 from the input buffer 52 and may process the data.

After a time interval necessary for processing the input data frame 66, the CPU 18 may compose an output data frame 68 for transfer to the programmer 40 during the second time interval t₂. As shown (FIG. 4), the output frame 68 may include one or more start bits, n bits for a reply or error code and m bits for a value. The composed output data frame 68 may be transferred from the CPU 18 to the output buffer 50.

Transfer of the output data frame 68 from the TCXO 10 to the programmer 40 may be timed to the clock signal applied to the SCLK pad 30. For example, where the clock signal is applied continuously to the SCLK pad 30, then the transfer of the output frame 68 may be initiated upon delivery to the output buffer 50. However, where the clock on the SCLK pad 30 is interrupted after the first time interval t₁ and before the beginning of the second time interval t₂, then transfer of the output frame 68 would only begin after resumption of the clock and then only upon detection of the falling edge of the first clock pulse once the clock is resumed.

The programmer 40 may detect the beginning of the second time interval t₂ by detection of the start bits of the output frame 68. A bit detector 45 within the programmer 40 may detect the beginning of the output frame 68. A counter 43 may be used to detect the end of the output frame 68 based upon the number of clock pulses following the start bit. At the end of the output frame 68 as determined by the counter 43, the bit detector 45 may notify the CPU 42 of the availability of the output frame 68 within the input buffer 44. The CPU 42 may retrieve the output frame 68, process the data and the process may repeat.

The transfer of an input frame 66 and receipt of an output frame 68 may represent the transfer of one complete communication frame. Once one communication frame is completed, another communication frame may be initiated.

Under another illustrated embodiment of the invention (FIG. 4), the input frame 72 may include a total of seventeen bits. Of the seventeen bits, one bit may be a start bit, four bits may be reserved for command coding and 12 bits may be reserved for an address or data value.

Similarly, the output frame 74 of FIG. 4 may also include seventeen bits. As with the input frame 72, the output frame 74 may include one start bit, four bits for a reply code or error code and twelve bits may be reserved for a data value.

A specific embodiment of a method and apparatus for exchanging data with a TCXO according to the present invention has been described for the purpose of illustrating the manner in which the invention is made and used. It should be understood that the implementation of other variations and modifications of the invention and its various aspects will be apparent to one skilled in the art, and that the invention is not limited by the specific embodiments described. Therefore, it is contemplated to cover the present invention and any and all modifications, variations, or equivalents that fall within the true spirit and scope of the basic underlying principles disclosed and claimed herein.

1. A method of exchanging data with a temperature controlled crystal oscillator chip, such method comprising the steps of:
receiving data within the temperature controlled crystal oscillator chip through a first bonding pad of the chip during a first time interval; and;
transmitting data from the temperature controlled crystal oscillator chip through the first bonding pad of the chip during a second time interval.

2. The method of exchanging data with the temperature controlled crystal oscillator chip as in claim 1 further comprising applying a clock signal to a second bonding pad of the chip.

3. The method of exchanging data with the temperature controlled crystal oscillator chip as in claim 2 further comprising synchronizing the transmitted and received data to the applied clock signal.

4. The method of exchanging data with the temperature controlled crystal oscillator chip as in claim 1 further comprising transferring a predetermined data frame within each of the first and second time intervals.

5. The method of exchanging data with the temperature controlled crystal oscillator chip as in claim 1 further comprising including a start bit within a predetermined location of the data frame.

6. The method of exchanging data with the temperature controlled crystal oscillator chip as in claim 1 further comprising reserving n-bits in the data frame for one of command code, reply code and error code.

7. The method of exchanging data with the temperature controlled crystal oscillator chip as in claim 6 further comprising reserving m-bits in the data frame for one of an address and a data value.

8. An apparatus for exchanging data with a temperature controlled crystal oscillator chip, such apparatus comprising:
means for receiving data within the temperature controlled crystal oscillator chip through a first bonding pad of the chip during a first time interval; and;
means for transmitting data from the temperature controlled crystal oscillator chip through the first bonding pad of the chip during a second time interval.

9. The apparatus for exchanging data with the temperature controlled crystal oscillator chip as in claim 8 further comprising means for applying a clock signal to a second bonding pad of the chip.

10. The apparatus for exchanging data with the temperature controlled crystal oscillator chip as in claim 9 further comprising means for synchronizing the transmitted and received data to the applied clock signal.

11. The apparatus for exchanging data with the temperature controlled crystal oscillator chip as in claim 8 further comprising means for transferring a predetermined data frame within each of the first and second time intervals.

12. The apparatus for exchanging data with the temperature controlled crystal oscillator chip as in claim 8 further comprising means for including a start bit within a predetermined location of the data frame.

13. The apparatus for exchanging data with the temperature controlled crystal oscillator chip as in claim 8 further comprising means for reserving n-bits in the data frame for one of command code, reply code and error code.

14. The apparatus for exchanging data with the temperature controlled crystal oscillator chip as in claim 13 further comprising means for reserving m-bits in the data frame for one of an address and a data value.

15. An apparatus for exchanging data with a temperature controlled crystal oscillator chip, such apparatus comprising:
an input buffer adapted to receiving data within the temperature controlled crystal oscillator chip through a first bonding pad of the chip during a first time interval; and;
an output buffer adapted to transmit data from the temperature controlled crystal oscillator chip through the first bonding pad of the chip during a second time interval.

16. The apparatus for exchanging data with the temperature controlled crystal oscillator chip as in claim 15 further comprising an external clock adapted to apply a clock signal to a second bonding pad of the chip.

17. The apparatus for exchanging data with the temperature controlled crystal oscillator chip as in claim 16 further comprising a synch controller adapted to synchronize the transmitted and received data to the applied clock signal.

18. The apparatus for exchanging data with the temperature controlled crystal oscillator chip as in claim 15 further comprising means for transferring a predetermined data frame within each of the first and second time intervals.

19. The apparatus for exchanging data with the temperature controlled crystal oscillator chip as in claim 15 further comprising means for including a start bit within a predetermined location of the data frame.

20. The apparatus for exchanging data with the temperature controlled crystal oscillator chip as in claim 15 further comprising means for reserving n-bits in the data frame for one of command code, reply code and error code.

21. The apparatus for exchanging data with the temperature controlled crystal oscillator chips in claim 20 further comprising means for reserving m-bits in the data frame for one of an address and a data value.
